(19) United States
(12) Patent Application Publication
(10) Pub. No.: US 2026/0157048 A1
(43) Pub. Date: Jun. 4, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Deng GAO, Hefei (CN); Yuan YAO, Hefei (CN); Peng QIN, Kunshan (CN); Bo RAO, Hefei (CN)

(73) Assignees: Hefei Visionox Technology Co., Ltd., Hefei (CN); Visionox Technology Inc., Kunshan (CN)

(21) Appl. No.: 19/399,656

(22) Filed: Nov. 25, 2025

(30) Foreign Application Priority Data
Nov. 30, 2024 (CN) 202411752878.0

(51) Int. Cl. H10K 59/122

(52) U.S. Cl. CPC H10K 59/122

(57) ABSTRACT

The present application relates to the field of display technologies, and specifically provides a display panel and a display apparatus. The display panel includes a substrate and a pixel define layer. The pixel define layer is located on a side of the substrate. The pixel define layer is provided with a plurality of pixel openings. The pixel define layer includes a first sidewall on a side facing the pixel openings. The pixel define layer further includes a first bottom wall on a side facing the substrate. In a direction perpendicular to a plane in which the substrate is located, an end of the first sidewall close to the substrate intersects the first bottom wall to form a slope angle. The slope angle is not greater than 60°. A shape of the pixel openings of the pixel define layer may be adjusted to improve the use performance of the display panel.

### CROSS-REFERENCE TO RELATED APPLICATIONS

This application claims priority to Chinese Patent Application No. 202411752878.0, filed on November 30, 2024, which is incorporated herein by reference in its entirety.

### FIELD

The present application relates to the field of display technologies, and in particular to a display panel and a display apparatus.

### BACKGROUND

Organic light-emitting diodes (OLED) and flat-panel display apparatuses based on technologies such as the organic light-emitting diodes (OLED) are widely used in various consumer electronics such as mobile phones, televisions, notebook computers, and desktop computers, and predominate in display apparatuses, due to their advantages such as high image quality, energy efficiency, slim design, and a wide range of applications.

However, the use performance of current OLED display products needs to be improved.

### SUMMARY

The present application provides a display panel and a display apparatus, to improve the use performance of a display panel at least to a specific extent.

Embodiments in the present application are as follows: In a first aspect, a display panel is provided, including a substrate and a pixel define layer. The pixel define layer is located on a side of the substrate. The pixel define layer is provided with a plurality of pixel openings. The pixel define layer includes a first sidewall on a side facing the pixel openings. The pixel define layer further includes a first bottom wall on a side facing the substrate.

In a direction perpendicular to a plane in which the substrate is located, an end of the first sidewall close to the substrate intersects the first bottom wall to form a slope angle, and the slope angle is not greater than 60°.

In the display panel provided in this embodiment of the present application, the first sidewall of the pixel define layer close to or pointing to the pixel opening is controlled to be a sloped sidewall, to form the slope angle not greater than 60° between the first sidewall and the first bottom wall, which can effectively reduce difficulty in climbing by subsequent film layers at the first sidewall, achieve desirable continuity between corresponding film layers at the first sidewall, avoid impact on impedance of the film layers, and reduce display abnormalities caused by poor continuity between the film layers at the first sidewall. This structural improvement helps improve the display effect and reliability of the display panel, and can improve the use performance of the display panel to a specific extent.

In a second aspect, the present application further provides a display panel, including a substrate and a pixel define layer. The pixel define layer is located on a side of the substrate. The pixel define layer is provided with a plurality of pixel openings. The pixel define layer includes a first sidewall on a side facing the pixel openings. The pixel define layer further includes a first bottom wall on a side facing the substrate.

In a direction perpendicular to a plane in which the substrate is located, an end of the first sidewall close to the substrate intersects the first bottom wall to form a slope angle. The plurality of pixel openings include at least a first opening and a second opening spaced apart from each other, and the slope angle of the first opening is greater than the slope angle of the second opening.

In a third aspect, the present application further provides a display apparatus, including the display panel described in any one of the above embodiments.

The display apparatus provided in this embodiment of the present application includes the above display panel, and the display apparatus includes at least the beneficial effects of any one or more of the above display panels. For the specific effects, references may be made to the above descriptions, which are not described herein again.

The beneficial effects of the display panel and the display apparatus provided in the present application are as follows: Compared with the related art, in the display panel provided in the present application, the shape of the first sidewall on the end of the pixel define layer pointing to the pixel opening may be adjusted, and the first sidewall is sloped relative to the first bottom wall to form the slope angle not greater than 60° with the first bottom wall, which can reduce the difficulty in climbing by the first electrode prepared at the first sidewall, improve continuity of the first electrode at the first sidewall, minimize a possibility of breaking or falling of the first electrode at the first sidewall, help reduce impedance of the first electrode at the first sidewall, ensure that relevant light-emitting devices have a relatively uniform light emission brightness, and reduce a possibility of display defects such as pixel dark spots. This structure can improve the reliability of the display panel and improve the display effect and the use performance of the display panel.

### BRIEF DESCRIPTION OF THE DRAWINGS

To describe the embodiments of the present application more clearly, the following briefly describes the accompanying drawings required for describing the embodiments or the prior art. Apparently, the accompanying drawings in the following description show merely some embodiments of the present application.

FIG. 1 is a schematic structural plan view of a display panel according to an embodiment of the present application;

FIG. 2 is an enlarged view of a structure of an area A in the display panel shown in FIG. 1;

FIG. 3 is a schematic view of a sectional structure of the display panel shown in FIG. 2;

FIG. 4 is an enlarged view of a structure of an area B in FIG. 3;

FIG. 5 is a schematic view of a second sectional structure of the display panel shown in FIG. 2;

FIG. 6 is a schematic view of an intermediate structure of the display panel according to an embodiment of the present application during preparation; and

FIG. 7 is a schematic structural plan view of a display apparatus according to an embodiment of the present application.

### Reference numerals in the figures:

1: substrate; 2: pixel define layer; 201: pixel opening; 201a: first opening; 201b: second opening; 21: first sidewall; 22: first bottom wall; 23: slope angle; 3: isolation structure; 301: isolation opening; 31: support portion; 311: support sub-portion; 32: crown; 4: light-emitting device; 41: light-emitting functional layer; 411: first light-emitting sub-portion; 412: second light-emitting sub-portion; 413: third light-emitting sub-portion; 42: first electrode; 43: second electrode; 5: encapsulation unit; 51: first encapsulation portion; 52: second encapsulation portion; 10: display panel; 100: display apparatus.

### DETAILED DESCRIPTION OF THE EMBODIMENTS

In order to make problems to be resolved in the present application, embodiments of the present application are further described in detail below with reference to the accompanying drawings and embodiments. It should be understood that the specific embodiments described herein are merely intended to explain the present application, and are not intended to limit the present application.

It should be noted that when an element is referred to as being "fixed to" or "arranged on" another element, it may be directly or indirectly on the another element. When an element is referred to as being "connected to" another element, it may be directly or indirectly connected to the another element.

In the description of the present application, it should be understood that orientation or position relationships indicated by the terms such as "center", "longitudinal", "transverse", "length", "width", "thickness", "on", "below", "front", "back", "left", "right", "vertical", "horizontal", "top", "bottom", "inside", "outside", "clockwise", "anticlockwise", "axial direction", "radial direction", and "peripheral direction" are based on orientation or position relationships shown in the drawings, and are merely used to facilitate description of the present application and simplify the description, rather than indicating or implying that an apparatus or an element referred to needs to have a particular orientation or be constructed and operated in a particular orientation. Therefore, such terms cannot be understood as a limitation on the present application.

In addition, the terms "first" and "second" are merely used for description, and cannot be understood as indicating or implying relative importance or implicitly indicating a quantity of indicated features. Therefore, features defined by "first" or "second" may explicitly or implicitly include one or more of the features. In the description of the present application, "a plurality of" means two or more, unless explicitly and specifically defined otherwise.

In the present application, unless otherwise explicitly specified and defined, the terms such as "mount", "connected", "connect", and "fix" should be understood in a broad sense. For example, they may be a fixed connection, a detachable connection, or an integral connection, or may be a mechanical connection, an electrical connection, or mutual communication; or may be a direct connection or an indirect connection through an intermediate medium, or may be communication between interiors of two elements or interaction between two elements.

In the present application, unless otherwise explicitly specified and defined, a first feature being "on" or "under" a second feature may mean that the first feature is in direct contact with the second feature, or the first feature is in indirect contact with the second feature by using an intermediate medium. In addition, the first feature being "above", "over", or "on" the second feature may mean that the first feature is directly or obliquely above the second feature, or merely indicate that the first feature is at a higher horizontal position than the second feature. The first feature being "below", "under", and "beneath" the second feature may mean that the first feature is directly or obliquely below the second feature, or merely indicate that the first feature is at a lower horizontal position than the second feature.

In the present application, the term "one embodiment," "some embodiments," "example," "specific example", "some examples", or the like means that specific features, structures, materials, or characteristics described in combination with the embodiment or example are included in at least one embodiment or example of the present application. In this specification, the schematic descriptions of the above terms do not necessarily refer to the same embodiment or example. In addition, the described specific features, structures, materials, or characteristics may be combined in a proper manner in any one or more embodiments or examples.

The term "layer" used herein may refer to a part of a material that includes an area having a specific thickness. The layer may extend over an entire underlying or overlying structure, or may have a smaller range than the underlying or overlying structure. In addition, the layer may be an area of a continuous structure that is homogeneous or non-homogeneous, and a thickness of the layer is less than a thickness of the continuous structure. For example, the layer may be located between top and bottom surfaces of the continuous structure or between any pair of transverse planes on the top and bottom surfaces. The layer may extend laterally, vertically, and/or along a tapered surface. A substrate may be a layer, may include one or more layers therein, and/or may have one or more layers located on, above, and/or below the substrate. The layer may include a plurality of layers. For example, an interconnection layer may include one or more conductor and contact layers (within which contacts, interconnect lines, and/or vias are formed), and one or more dielectric layers.

During implementation of the present application, the inventors have found that there are the following problems in the related art. Some pixel units have display abnormalities, which affects a display effect of a display panel 10 to a specific extent, affecting the use performance of the display panel and reducing the reliability of the display panel 10.

Based on this, an embodiment of the present application provides a display panel 10, to alleviate or ameliorate the problem at least to a specific extent.

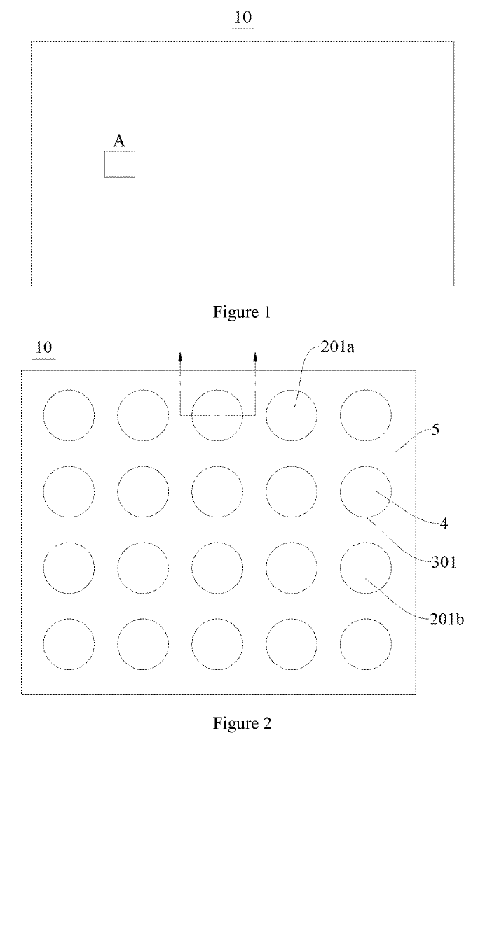

Referring to FIG. 1 and FIG. 2, an embodiment of the present application provides a display panel 10. The display panel 10 includes a substrate 1 and a pixel define layer 2. The pixel define layer 2 is located on a side of the substrate 1. In a direction perpendicular to a plane in which the substrate 1 is located, initial thicknesses at all positions of the pixel define layer 2 are substantially the same.

The display panel 10 further includes an isolation structure 3. The isolation structure 3 is located on a side of the pixel define layer 2 facing away from the substrate 1. The pixel define layer 2 is located between the isolation structure 3 and the substrate 1.

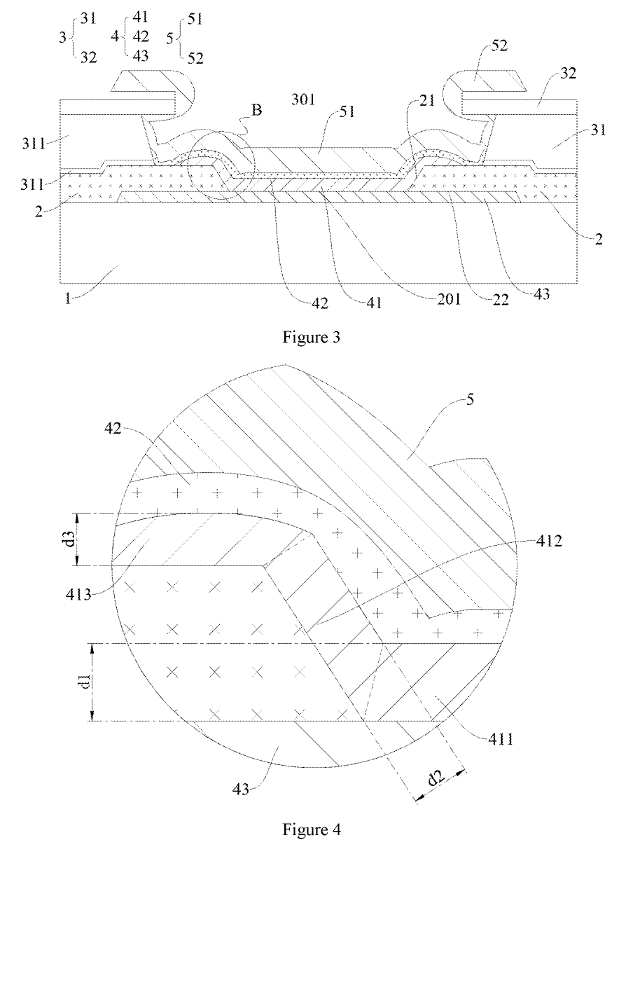

Referring to FIG. 2 and FIG. 3, the isolation structure 3 encloses a plurality of isolation openings 301. The pixel define layer 2 is provided with a plurality of pixel openings 201. The isolation openings 301 are arranged corresponding to and in communication with the pixel openings 201.

The pixel define layer 2 includes a first sidewall 21 on a side facing the pixel openings 201. The pixel define layer 2 further includes a first bottom wall 22 on a side facing the substrate 1. In the direction perpendicular to the plane in which the substrate 1 is located, an end of the first sidewall 21 close to the substrate 1 intersects the first bottom wall 22 to form a slope angle 23. The slope angle 23 is not greater than 60°.

Content of the isolation structure 3 mentioned below is further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A for reference.

Referring to FIG. 2, a plurality of pixel openings 201 are provided. The plurality of pixel openings 201 include at least a first opening 201a and a second opening 201b spaced apart in sequence in an extension direction of the pixel define layer 2. Correspondingly, the isolation openings 301 are arranged in a one-to-one correspondence with and in communication with the first opening 201a and the second opening 201b.

The pixel define layer 2 can form a slope angle 23 at any one of the pixel openings 201 (for example, the first opening 201a, the second opening 201b, or another opening). The slope angles at different pixel openings 201 may be the same, or may be different.

Referring to FIG. 3 and FIG. 4, there is a spacing between an orthographic projection of an end, of a first sidewall 21 formed at a pixel opening 201, facing away from the substrate 1 on the substrate 1 and an orthographic projection of an end close to the substrate 1 on the substrate 1, and the orthographic projection of the end facing away from the substrate 1 on the substrate 1 is outside the orthographic projection of the end close to the substrate 1 on the substrate 1 (i.e., outside the pixel opening 201). The first sidewall 21 and the first bottom wall 22 intersect to form the slope angle 23 pointing to a middle of the pixel opening 201. The slope angle 23 is not greater than 60°.

In the display panel 10 provided in this embodiment of the present application, the first sidewall 21 of the pixel define layer 2 close to or pointing to the pixel opening 201 is controlled to be a sloped sidewall, to form the slope angle 23 not greater than 60° between the first sidewall 21 and the first bottom wall 22. In this case, the sloped first sidewall 21 causes a film layer thickness of the pixel define layer 2 to slowly increase toward a side away from the pixel opening 201, and a thickness variation in a film layer area in which the first sidewall 21 configured to support a subsequent process is located is gentle, which facilitates smooth attachment and overlapping of subsequent film layers at the first sidewall 21, thereby reducing difficulty in climbing by the subsequent film layers at the first sidewall 21, achieving desirable continuity between corresponding film layers at the first sidewall, avoiding impact on impedance of the film layers, and reducing display abnormalities caused by poor continuity between the film layers at the first sidewall 21. This structural improvement helps improve the display effect and reliability of the display panel 10, and can improve the use performance of the display panel 10 to a specific extent.

For example, when a surface of the first sidewall 21 needs to overlap a light-emitting device 4, the relatively flat first sidewall 21 allows the light-emitting device 4 to overlap the first sidewall 21 smoothly, helping improve continuity between the film layers.

In some embodiments, the surface of the first sidewall 21 is a smooth surface, or may be a surface with low roughness.

In order to facilitate processing of the pixel define layer 2 to obtain the slope angle 23, in some embodiments, a material of the pixel define layer 2 includes an inorganic material.

In this embodiment, the pixel define layer 2 may be processed through dry etching to obtain the pixel opening 201, and also obtain the slope angle 23.

Due to the directional property of dry etching, it can be ensured that the prepared pixel opening 201 is etched relatively accurately, to achieve a clear and regular edge of the first sidewall 21 enclosing the pixel opening 201, which has a shape satisfying a design requirement.

Specifically, the slope angle 23 is not less than 30°.

Referring to FIG. 3, the slope angle 23 ranges from 30° to 60°. The specific value range of the slope angle may be adjusted according to an actual requirement. For example, the angle may be any one of 30°, 35°, 40°, 45°, 50°, 55°, or 60°.

In other embodiments, the slope angle 23° may be set to be ranging from 40° to 50°. In this case, the slope angle 23 may be any one of 30°, 35°, 40°, 45°, or 50°.

When the slope angle 23 is excessively large, the first sidewall 21 is relatively steep, affecting a thickness and continuity of a film layer subsequently attached thereto. When the slope angle 23 is excessively small, a length of a part of the first sidewall 21 protruding toward the pixel opening 201 is excessively large, affecting an opening size of the pixel opening 201 and affecting the display effect of the display panel 10.

It should also be noted that a part of the first sidewall 21 that is in contact with the first bottom wall 22 cannot be located on a side away from the pixel opening 201 relative to the first sidewall 21. Otherwise, a peripheral side edge of the pixel define layer 2 close to the pixel opening 201 forms an inverted taper angle structure, which further increases difficulty in overlapping subsequent film layers on the first sidewall 21, or even leads to direct breaking of a cathode at the first sidewall.

Referring to FIG. 3 and FIG. 4, the display panel 10 further includes a light-emitting device layer. The light-emitting device layer is located on the substrate 1 and includes a plurality of light-emitting devices 4 located in the corresponding isolation openings 301. The isolation openings 301 are configured to accommodate the light-emitting devices 4. Each of the light-emitting devices 4 includes at least a light-emitting functional layer 41 and a first electrode 42 that are stacked.

Specifically, the light-emitting functional layer 41 covers the pixel opening 201 and the light-emitting functional layer 41 covers at least part of the first sidewall 21, and the first electrode 42 covers a side of the light-emitting functional layer 41 facing away from the substrate 1 and is in contact with a sidewall on a side of the isolation structure 3 facing the isolation opening 301.

An orthographic projection of the pixel opening 201 on the substrate 1 is within an orthographic projection of the light-emitting functional layer 41 on the substrate 1.

Specifically, the light-emitting functional layer 41 may be made from a small-molecule organic light emitting material, a complex light emitting material, a high-molecular polymer, and the like. Different light-emitting functional layers 41 can emit light of different colors. Generally, three types of light-emitting functional layers 41 are arranged, which are respectively configured to emit red, green, and blue light. For example, the light-emitting functional layer 41 is an organic functional layer located between the first electrode 42 and the second electrode 43, and the light-emitting functional layer 41 may specifically include one or more of organic functional layers among a light-emitting layer, an electron transport layer, an electron injection layer, a hole transport layer, and a hole injection layer.

One or more of the three different light-emitting functional layers 41 may be respectively arranged in the different isolation openings 301 according to a design requirement.

Referring to FIG. 3, the light-emitting functional layer 41 includes a first light-emitting sub-portion 411 and a second light-emitting sub-portion 412, the first light-emitting sub-portion 411 covers the pixel opening 201, and the second light-emitting sub-portion 412 covers at least part of the first sidewall 21.

The light-emitting functional layer 41 may be prepared through evaporation. A larger slope angle 23 indicates a smaller thickness of the second light-emitting sub-portion 412 formed on the first sidewall 21 through evaporation. Correspondingly, higher difficulty in climbing along the second light-emitting sub-portion 412 by the first electrode 42 located on the side of the light-emitting functional layer 41 facing away from the substrate 1 indicates a higher possibility that a film layer discontinuity defect occurs on the first electrode 42 on a side of the second light-emitting sub-portion 412 facing away from the substrate 1. When the discontinuity defect occurs on the first electrode 42, the impedance of the first electrode 42 increases, affecting the display effect of the light-emitting device 4, and resulting in low brightness of the light-emitting device 4.

Referring to FIG. 4, a thickness d2 of the second light-emitting sub-portion 412 is less than a thickness d1 of the first light-emitting sub-portion 411.

In the case in which different slope angles 23 are formed at different pixel openings 201, the first opening 201a and the second opening 201b are taken as an example. The first opening 201a and the second opening 201b are spaced apart on the pixel define layer 2, and the slope angle 23 formed at the first opening 201a is greater than the slope angle 23 formed at the second opening 201b. Correspondingly, a ratio of the thickness of the second light-emitting sub-portion 412 arranged at the first opening 201a to the thickness of the corresponding first light-emitting sub-portion 411 is less than a ratio of the thickness of the second light-emitting sub-portion 412 arranged at the second opening 201b to the thickness of the corresponding first light-emitting sub-portion 411.

A ratio of the thickness of the second light-emitting sub-portion 412 to the thickness of the first light-emitting sub-portion 411 is negatively correlated with a magnitude of the slope angle 23.

In another embodiment, the second light-emitting sub-portion 412 arranged at the first opening 201a and the second light-emitting sub-portion 412 arranged at the second opening 201b emit light of a same color, and the thickness of the second light-emitting sub-portion 412 arranged at the first opening 201a is less than the thickness of the second light-emitting sub-portion 412 arranged at the second opening 201b.

A larger ratio of the thickness of the second light-emitting sub-portion 412 to the thickness of the corresponding first light-emitting sub-portion 411 or a larger thickness of the second light-emitting sub-portion 412 correspondingly indicates lower difficulty in climbing along the second light-emitting sub-portion 412 by the first electrode 42 located on the side of the light-emitting functional layer 41 facing away from the substrate 1 and a lower possibility that a discontinuity defect occurs on the first electrode 42 on the second light-emitting sub-portion 412. Therefore, adjusting the slope angle 23 without changing other processing conditions helps improve film layer continuity of the first electrode 42, thereby reducing the impedance of the first electrode 42 and optimizing the display effect of the light-emitting device 4.

In addition, the thickness of the second light-emitting sub-portion 412 affects to a specific extent heat generation of the first electrode 42 during operation. If the second light-emitting sub-portion 412 is excessively thin, the first electrode 42 may experience local overheating in an energized state, which accelerates aging and degradation of the material of the first electrode 42, and reduces stability and a service life of the first electrode 42.

The second light-emitting sub-portion 412 of the light-emitting functional layer 41 is attached to the surface of the first sidewall 21. Referring to FIG. 4, due to impact of the sloped first sidewall 21, the thickness d2 of the second light-emitting sub-portion 412 is less than the thickness d1 of the first light-emitting sub-portion 411. For example, the thickness of the second light-emitting sub-portion 412 may be a film layer thickness measured in a direction perpendicular to a plane in which the first sidewall 21 of the pixel define layer 2 is located. It should be noted that when the film layer thickness is non-uniform, the thickness of the corresponding light-emitting portion may be an average thickness or a thickness of a part corresponding to a middle position of an area in which the film layer is located. In some embodiments, an orthographic projection of the second light-emitting sub-portion 412 on the substrate 1 coincides with an orthographic projection of the first sidewall 21 on the substrate 1, in which case the second light-emitting sub-portion 412 covers the first sidewall 21 of the pixel define layer 2.

When the slope angle 23 of the pixel define layer 2 ranges from 30° to 60°, in the same pixel opening 201, the thickness d2 of the second light-emitting sub-portion 412 is not less than 50% of the thickness d1 of the first light-emitting sub-portion 411.

Since the ratio of the thickness of the second light-emitting sub-portion 412 to the thickness of the first light-emitting sub-portion 411 is negatively correlated with the magnitude of the slope angle 23, a larger slope angle 23 indicates a smaller thickness of the second light-emitting sub-portion 412.

In this embodiment, when the slope angle 23 is 60°, the thickness of the second light-emitting sub-portion 412 is 50% of the thickness of the first light-emitting sub-portion 411. When the slope angle 23 is 30°, the thickness of the second light-emitting sub-portion 412 is 95% of the thickness of the first light-emitting sub-portion 411.

Specifically, in the same pixel opening 201, the ratio of the thickness of the second light-emitting sub-portion 412 to the thickness of the first light-emitting sub-portion 411 ranges from 50% to 95%.

Through the adjustment of the slope angle 23, the thickness of the second light-emitting sub-portion 412 attached to the first sidewall 21 can be adjusted without changing other parameters, to help reduce the difficulty in climbing over the first sidewall 21 by the first electrode 42, thereby reducing the impedance of the first electrode 42.

In other similar embodiments, the light-emitting functional layer 41 includes a first light-emitting sub-portion 411, a second light-emitting sub-portion 412, and a third light-emitting sub-portion 413. For structures of the first light-emitting sub-portion 411 and the second light-emitting sub-portion 412, references may be made to those described above. The third light-emitting sub-portion 413 is located on the side of the pixel define layer 2 facing away from the substrate 1. In the same pixel opening 201, the second light-emitting sub-portion 412 is located between the first light-emitting sub-portion 411 and the third light-emitting sub-portion 413 and is connected to the first light-emitting sub-portion 411 and the third light-emitting sub-portion 413.

Specifically, a thickness d3 of the third light-emitting sub-portion 413 is not greater than the thickness d1 of the first light-emitting sub-portion 411.

Due to impact of an evaporation angle, the thickness d3 of the third light-emitting sub-portion 413 may be substantially the same as the thickness d1 of the first light-emitting sub-portion 411, or may be slightly less than the thickness d1 of the first light-emitting sub-portion 411.

The film layer thickness of the first light-emitting sub-portion 411 remains substantially the same at different positions.

Referring to FIG. 3, and orthographic projection of the third light-emitting sub-portion 413 on the substrate 1 is spaced apart from an orthographic projection of a side of the isolation structure 3 close to the substrate 1 on the substrate 1. In other words, the light-emitting functional layer 41 is in a non-contact state with the isolation structure 3.

The first electrode 42 located on the side of the light-emitting functional layer 41 facing away from the substrate 1 covers the light-emitting functional layer 41 and overlaps a part of a sidewall on the side of the isolation structure 3 close to the substrate 1.

Referring to FIG. 3, the light-emitting device 4 further includes a second electrode 43. The second electrode 43 is located between the pixel define layer 2 and the substrate 1. The orthographic projection of the pixel opening 201 on the substrate 1 is within an orthographic projection of the second electrode 43 on the substrate 1. The light-emitting functional layer 41 passes through the pixel opening 201 to come into contact with the second electrode 43.

The light-emitting functional layer 41 is located between the first electrode 42 and the second electrode 43.

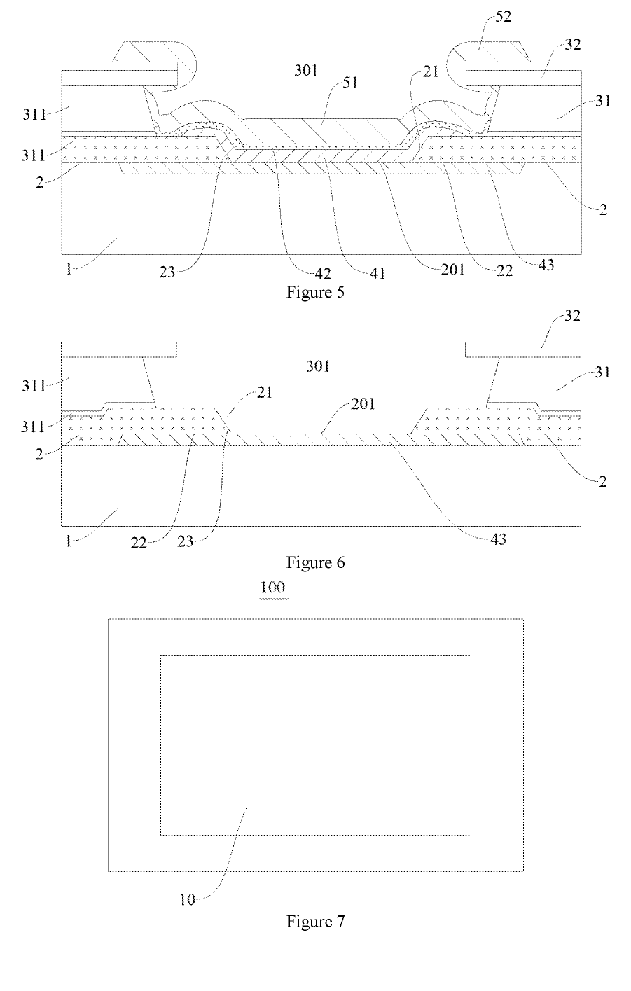

Referring to FIG. 3 and FIG. 5, the second electrode 43 is located between the pixel define layer 2 and the substrate 1.

One of the first electrode 42 and the second electrode 43 that form the light-emitting device 4 is an anode, and the other is a cathode.

In this embodiment, the first electrode 42 is a cathode, and the second electrode 43 is an anode. Certainly, in other similar embodiments, as needed, the first electrode 42 may be adjusted to be an anode, and the second electrode 43 may be adjusted to be a cathode.

The isolation structure 3 may achieve isolation between the light-emitting functional layers 41 located in different isolation openings 301 and the first electrode 42 by using the isolation openings 301, and the light-emitting functional layers 41 located in the different isolation openings 301 and the first electrode 42 can remain independent of and unconnected to each other.

A shape of the isolation structure 3 that encloses the isolation opening 301 is described in detail below.

The isolation structure 3 includes a support portion 31 and a crown 32. The crown 32 is located on a side of the support portion 31 facing away from the substrate 1.

An orthographic projection of the support portion 31 on the substrate 1 is within an orthographic projection of the crown 32 on the substrate 1.

In the direction perpendicular to the plane in which the substrate 1 is located, a sectional shape of a part of the isolation structure 3 located between two adjacent isolation openings 301 resembles a rectangular or trapezoidal structure, or the sectional shape of the isolation structure 3 may be in a shape that is wider at the top and narrower at the bottom. An orthographic projection of an end of the isolation structure 3 close to the substrate 1 on the substrate 1 is within an orthographic projection of an end of the isolation structure 3 facing away from the substrate 1 on the substrate 1.

Specifically, the support portion 31 may be a single-layer structure or a multi-layer structure.

In some embodiments, when the support portion 31 is a multi-layer structure, the support portion 31 includes at least two support sub-portions 311 that are stacked. An orthographic projection of a support sub-portion 311 away from the substrate 1 on the substrate 1 is within an orthographic projection of a support sub-portion 311 close to the substrate 1 on the substrate 1.

It may be determined through observation of FIG. 3 that the orthographic projection of the support sub-portion 311 close to the substrate 1 on the substrate 1 is within the orthographic projection of the crown 32 on the substrate 1.

In the direction perpendicular to the plane in which the substrate 1 is located, a sectional contour of a part of the support sub-portion 311 located between two adjacent isolation openings 301 is in a shape of one of a rectangle, a trapezoid, or an inverted trapezoid. Similarly, in the direction perpendicular to the plane in which the substrate 1 is located, a sectional contour of a part of the crown 32 located between two adjacent isolation openings 301 is in a shape of one of a trapezoid, a rectangle, or an inverted trapezoid.

Referring to FIG. 3, the sectional contours of the crown 32 and the support sub-portion 311 that is close to the substrate 1 are in a shape of a rectangle, and the sectional contour of the support sub-portion 311 away from the substrate 1 may be in a shape of a rectangle or a regular trapezoid.

In some embodiments, a sidewall on a side, of the support sub-portion 311 away from the substrate 1, facing the isolation opening 301 is offset toward a side away from the isolation opening 301 relative to a sidewall on a side, of the support sub-portion 311 away from the substrate 1, facing the isolation opening 301, and a sectional sidewall of the isolation structure 3 is in a shape similar to an eave.

Certainly, in other same or similar embodiments, the dimension and projection relationships between the support portion 31 and the crown 32 may be adaptively adjusted according to a design requirement.

In some embodiments, the two support sub-portions 311 and the crown 32 may be an integrally formed structure, or may be obtained by sequentially stacking different materials.

Specifically, a material of the crown 32 includes metallic titanium, which is a titanium metal layer. A material of the support sub-portion 311 includes either metallic aluminum or metallic molybdenum. For example, the material of the support sub-portion 311 close to the substrate 1 includes metallic molybdenum, which is a molybdenum metal layer. The material of the support sub-portion 311 away from the substrate 1 includes metallic aluminum, which is an aluminum metal layer.

Referring to FIG. 3, the first electrode 42 can overlap a sidewall on a side of the molybdenum metal layer close to the isolation opening 301. In one embodiment, the first electrode 42 can overlap sidewalls on sides of both the molybdenum metal layer and the aluminum metal layer close to the isolation opening 301.

Referring to FIG. 3 and FIG. 5, the display panel 10 further includes an encapsulation layer.

The encapsulation layer includes a plurality of encapsulation units 5 spaced apart from each other. The encapsulation units 5 are arranged corresponding to the isolation openings 301, and are configured to encapsulate the light-emitting devices 4 arranged in the isolation openings 301.

Specifically, the encapsulation unit 5 includes a first encapsulation portion 51 and a second encapsulation portion 52 that are connected, the first encapsulation portion 51 is located on a side of the first electrode 42 facing away from the substrate 1 and covers a sidewall on the side of the isolation structure 3 facing the isolation opening 301, and the second encapsulation portion 52 is on a side of the isolation structure 3 facing away from the substrate 1.

Referring to FIG. 3 and FIG. 5, the first encapsulation portion 51 covers a side of the light-emitting device 4 facing away from the substrate 1, covers at least part of a sidewall on the side of the isolation structure 3 facing the isolation opening 301, and is connected, through the crown 32 of the isolation structure 3, to the second encapsulation portion 52 located on the side of the isolation structure 3 facing away from the substrate 1.

A gap exists between the second encapsulation portion 52 and the surface on the side of the isolation structure 3 facing away from the substrate 1, in which case the second encapsulation portion 52 is floated relative to the isolation structure 3.

In each isolation opening 301, the encapsulation unit 5 formed by the first encapsulation portion 51 and the second encapsulation portion 52 is a continuous film layer structure, to provide a desirable encapsulation effect for the isolation structure 3 and the light-emitting device 4 located in the isolation opening 301.

In a pixel opening 201, if the slope angle 23 corresponding to the pixel opening 201 is relatively small, the side of the light-emitting device 4 facing away from the substrate 1 can form a relatively flat shape after the light-emitting device 4 is arranged in the isolation opening 301 corresponding to the pixel opening 201. When the encapsulation unit 5 encapsulates the isolation structure 3 and the light-emitting device 4 located in the isolation opening 301, the relatively flat shape helps reduce encapsulation difficulty, thereby avoiding cracks caused by excessively thin encapsulation film layers in a part of an area, and improving a final encapsulation effect.

After the isolation opening 301 is encapsulated using the encapsulation layer, another film layer structure needs to be further arranged on a side of the encapsulation layer facing away from the substrate 1 for further planarization, encapsulation, and the like of the display panel 10.

Specifically, the side of the encapsulation layer facing away from the substrate 1 is further provided with at least one layer of film layer structure among a planarization layer, an organic encapsulation film layer, an inorganic encapsulation film layer, a touch layer, an organic adhesive layer, and a cover plate.

Taking the planarization layer as an example, a material of the planarization layer may include at least one of an organic material or an inorganic material, for example, an organic polymer (such as polyimide or acrylic resin) or an inorganic material (such as silicon oxide or silicon nitride).

The planarization layer made of the organic material may be prepared using a technology such as an ink‑jet printing (IJP) technology. A part of the planarization layer may flow into the isolation opening 301, which fills the isolation opening 301 to improve flatness of the display panel 10, while providing specific protection to the relevant film layers located below the planarization layer. Another part of the planarization layer may cover the above first encapsulation portion 51 and fill a gap formed between the first encapsulation portion 51 and the isolation structure 3. A side surface of the finally prepared planarization layer facing away from the substrate 1 is a flat surface.

It may be understood that, in the display panel 10 provided in this embodiment of the present application, the shape of the first sidewall 21 on the end of the pixel define layer 2 pointing to the pixel opening 201 may be adjusted, and the first sidewall is sloped relative to the first bottom wall 22 to form the slope angle 23 not greater than 60° with the first bottom wall 22, which can reduce the difficulty in climbing by the first electrode 42 prepared at the first sidewall 21, improve continuity of the first electrode 42 at the first sidewall 21, minimize a possibility of breaking or falling of the first electrode 42 at the first sidewall, help reduce impedance of the first electrode 42 at the first sidewall, ensure that relevant light-emitting devices 4 have a relatively uniform light emission brightness, and reduce a possibility of display defects such as pixel dark spots. This structure can improve the reliability of the display panel 10 and improve the display effect and the use performance of the display panel 10.

Referring to FIG. 1 to FIG. 5, the present application further provides another display panel.

The display panel 10 includes a substrate 1 and a pixel define layer 2. The pixel define layer 2 is located on a side of the substrate 1. In a direction perpendicular to a plane in which the substrate 1 is located, initial thicknesses at all positions of the pixel define layer 2 are substantially the same.

The pixel define layer 2 is provided with a plurality of pixel openings 201. The pixel define layer 2 includes a first sidewall 21 on a side facing the pixel openings 201, and the pixel define layer 2 further includes a first bottom wall 22 on a side facing the substrate 1. In a direction perpendicular to a plane in which the substrate 1 is located, an end of the first sidewall 21 close to the substrate 1 intersects the first bottom wall 22 to form a slope angle 23.

Referring to FIG. 2, the plurality of pixel openings 201 include at least a first opening 201a and a second opening 201b spaced apart in an extension direction of the pixel define layer 2. The pixel define layer 2 can form a slope angle 23 at any one of the pixel openings 201 (for example, the first opening 201a, the second opening 201b, or another opening). The slope angles at different pixel openings 201 may be the same, or may be different.

In some embodiments, at least the slope angle 23 at the first opening 201a is different from the slope angle 23 at the second opening 201b.

Specifically, the slope angle 23 at the first opening 201a is greater than the slope angle 23 at the second opening 201b.

The slope angle 23 may affect the display effect of the display panel 10 to a specific extent. When the slope angle 23 of the pixel opening 201 is small, light emitted by a light-emitting device 4 is subjected to less blocking and reflection when being emitted, and more light can be smoothly emitted. In contrast, when the slope angle 23 is large, the light emitted by the light-emitting device 4 may be subjected to more blocking and reflection when being emitted through the pixel opening 201, resulting in an increased loss of the emitted light, and affecting the light emission brightness and the display effect.

Based on this principle, because different light-emitting devices 4 of different colors may need different light emission brightness, in the present application, the slope angles 23 of the pixel openings 201 corresponding to the light-emitting devices 4 of different colors may be adjusted to be different based on this requirement, to adjust the light emission brightness of the light-emitting devices 4 of different colors to a specific extent, to alleviate a problem of color imbalance and color cast that may exist in the display panel 10, and improve accuracy and richness of color display of the display panel 10.

Referring to FIG. 3 and FIG. 4, there is a spacing between an orthographic projection of an end, of a first sidewall 21 formed at a pixel opening 201, facing away from the substrate 1 on the substrate 1 and an orthographic projection of an end close to the substrate 1 on the substrate 1, and the orthographic projection of the end facing away from the substrate 1 on the substrate 1 is outside the orthographic projection of the end close to the substrate 1 on the substrate 1 (i.e., outside the pixel opening 201). The first sidewall 21 and the first bottom wall 22 intersect to form the slope angle 23 pointing to a middle of the pixel opening 201. The slope angle 23 is not greater than 60°.

The angle limitation can further improve the function of the light-emitting device 4 while achieving the adjustment of the light emission effect of the light-emitting device 4 corresponding to the pixel opening 201.

Specifically, the sloped first sidewall 21 causes a film layer thickness of the pixel define layer 2 to slowly increase toward a side away from the pixel opening 201, and a thickness variation in a film layer area in which the first sidewall 21 configured to support a subsequent process is located is gentle, which facilitates smooth attachment and overlapping of subsequent film layers at the first sidewall 21, thereby reducing difficulty in climbing by the subsequent film layers at the first sidewall 21, achieving desirable continuity between corresponding film layers at the first sidewall, avoiding impact on impedance of the film layers, and reducing display abnormalities caused by poor continuity between the film layers at the first sidewall 21. This structural improvement helps improve the display effect and reliability of the display panel 10, and can improve the use performance of the display panel 10 to a specific extent.

For example, when a surface of the first sidewall 21 needs to overlap a light-emitting device 4, the relatively flat first sidewall 21 allows the light-emitting device 4 to overlap the first sidewall 21 smoothly, helping improve continuity between the film layers.

In some embodiments, the surface of the first sidewall 21 is a smooth surface, or may be a surface with low roughness.

In order to facilitate processing of the pixel define layer 2 to obtain the slope angle 23, in some embodiments, a material of the pixel define layer 2 includes an inorganic material.

In this embodiment, the pixel define layer 2 may be processed through dry etching to obtain the pixel opening 201, and also obtain the slope angle 23.

Due to the directional property of dry etching, it can be ensured that the prepared pixel opening 201 is etched relatively accurately, to achieve a clear and regular edge of the first sidewall 21 enclosing the pixel opening 201, which has a shape satisfying a design requirement.

Specifically, the slope angle 23 is not less than 30°.

Referring to FIG. 3, the slope angle 23 ranges from 30° to 60°. The specific value range of the slope angle may be adjusted according to an actual requirement. For example, the angle may be any one of 30°, 35°, 40°, 45°, 50°, 55°, or 60°.

In other embodiments, the slope angle 23° may be set to be ranging from 40° to 50°. In this case, the slope angle 23 may be any one of 30°, 35°, 40°, 45°, or 50°.

When the slope angle 23 is excessively large, the first sidewall 21 is relatively steep, affecting a thickness and continuity of a film layer subsequently attached thereto. When the slope angle 23 is excessively small, a length of a part of the first sidewall 21 protruding toward the pixel opening 201 is excessively large, affecting an opening size of the pixel opening 201 and affecting the display effect of the display panel 10.

It should also be noted that a part of the first sidewall 21 that is in contact with the first bottom wall 22 cannot be located on a side away from the pixel opening 201 relative to the first sidewall 21. Otherwise, a peripheral side edge of the pixel define layer 2 close to the pixel opening 201 forms an inverted taper angle structure, which further increases difficulty in overlapping subsequent film layers on the first sidewall 21, or even leads to direct breaking of a cathode at the first sidewall.

The light-emitting device 4 described above includes a light-emitting functional layer 41, a first electrode 42, and a second electrode 43, and a structure of the device is described below in detail.

The light-emitting functional layer 41 is arranged corresponding to the pixel opening 201. The light-emitting functional layer 41 can cover the pixel opening 201 and cover at least part of the first sidewall 21, and the first electrode 42 covers the side of the light-emitting functional layer 41 facing away from the substrate 1. The second electrode 43 is located between the pixel define layer 2 and the substrate 1. The orthographic projection of the pixel opening 201 on the substrate 1 is within the orthographic projection of the second electrode 43 on the substrate 1. The light-emitting functional layer 41 passes through the pixel opening 201 to come into contact with the second electrode 43.

Specifically, the light-emitting functional layer 41 may be made from a small-molecule organic light emitting material, a complex light emitting material, a high-molecular polymer, and the like. Different light-emitting functional layers 41 can emit light of different colors. Generally, three types of light-emitting functional layers 41 are arranged, which are respectively configured to emit red, green, and blue light.

One or more of the three different light-emitting functional layers 41 may be respectively arranged in the different isolation openings 301 according to a design requirement.

Referring to FIG. 3, the light-emitting functional layer 41 includes a first light-emitting sub-portion 411 and a second light-emitting sub-portion 412, the first light-

emitting sub-portion 411 covers the pixel opening 201, and the second light-emitting sub-portion 412 covers at least part of the first sidewall 21.

The light-emitting functional layer 41 may be prepared through evaporation. A larger slope angle 23 indicates a smaller thickness of the second light-emitting sub-portion 412 formed on the first sidewall 21 through evaporation. Correspondingly, higher difficulty in climbing along the second light-emitting sub-portion 412 by the first electrode 42 located on the side of the light-emitting functional layer 41 facing away from the substrate 1 indicates a higher possibility that a film layer discontinuity defect occurs on the first electrode 42 on a side of the second light-emitting sub-portion 412 facing away from the substrate 1. When the discontinuity defect occurs on the first electrode 42, the impedance of the first electrode 42 increases, affecting the display effect of the light-emitting device 4, and resulting in low brightness of the light-emitting device 4.

Referring to FIG. 4, at the same pixel opening 201, the thickness of the second light-emitting sub-portion 412 is less than the thickness of the first light-emitting sub-portion 411.

In the case in which different slope angles 23 are formed at different pixel openings 201, the first opening 201a and the second opening 201b are taken as an example. The first opening 201a and the second opening 201b are spaced apart on the pixel define layer 2, and the slope angle 23 formed at the first opening 201a is greater than the slope angle 23 formed at the second opening 201b. Correspondingly, a ratio of the thickness of the second light-emitting sub-portion 412 arranged at the first opening 201a to the thickness of the corresponding first light-emitting sub-portion 411 is less than a ratio of the thickness of the second light-emitting sub-portion 412 arranged at the second opening 201b to the thickness of the corresponding first light-emitting sub-portion 411.

A ratio of the thickness of the second light-emitting sub-portion 412 to the thickness of the first light-emitting sub-portion 411 is negatively correlated with a magnitude of the slope angle 23.

In another embodiment, the second light-emitting sub-portion 412 arranged at the first opening 201a and the second light-emitting sub-portion 412 arranged at the second opening 201b emit light of a same color, and the thickness of the second light-emitting sub-portion 412 arranged at the first opening 201a is less than the thickness of the second light-emitting sub-portion 412 arranged at the second opening 201b.

A larger ratio of the thickness of the second light-emitting sub-portion 412 to the thickness of the corresponding first light-emitting sub-portion 411 or a larger thickness of the second light-emitting sub-portion 412 correspondingly indicates lower difficulty in climbing along the second light-emitting sub-portion 412 by the first electrode 42 located on the side of the light-emitting functional layer 41 facing away from the substrate 1 and a lower possibility that a discontinuity defect occurs on the first electrode 42 on the second light-emitting sub-portion 412. Therefore, adjusting the slope angle 23 without changing other processing conditions helps improve film layer continuity of the first electrode 42, thereby reducing the impedance of the first electrode 42 and optimizing the display effect of the light-emitting device 4.

In addition, the thickness of the second light-emitting sub-portion 412 affects to a specific extent heat generation of the first electrode 42 during operation. If the second light-emitting sub-portion 412 is excessively thin, the first electrode 42 may experience local overheating in an energized state, which accelerates aging and degradation of the material of the first electrode 42, and reduces stability and a service life of the first electrode 42.

The second light-emitting sub-portion 412 of the light-emitting functional layer 41 is attached to the surface of the first sidewall 21. Referring to FIG. 4, due to impact of the sloped first sidewall 21, the thickness d2 of the second light-emitting sub-portion 412 is less than the thickness d1 of the first light-emitting sub-portion 411.

In some embodiments, an orthographic projection of the second light-emitting sub-portion 412 on the substrate 1 coincides with an orthographic projection of the first sidewall 21 on the substrate 1, in which case the second light-emitting sub-portion 412 covers the first sidewall 21 of the pixel define layer 2.

When the slope angle 23 of the pixel define layer 2 ranges from 30° to 60°, in the same pixel opening 201, the thickness d2 of the second light-emitting sub-portion 412 is not less than 50% of the thickness d1 of the first light-emitting sub-portion 411.

In this embodiment, when the slope angle 23 is 60°, the thickness of the second light-emitting sub-portion 412 is 50% of the thickness of the first light-emitting sub-portion 411. When the slope angle 23 is 30°, the thickness of the second light-emitting sub-portion 412 is 95% of the thickness of the first light-emitting sub-portion 411.

Specifically, in the same pixel opening 201, the ratio of the thickness of the second light-emitting sub-portion 412 to the thickness of the first light-emitting sub-portion 411 ranges from 50% to 95%.

Through the adjustment of the slope angle 23, the thickness of the second light-emitting sub-portion 412 attached to the first sidewall 21 can be adjusted without changing other parameters, to help reduce the difficulty in climbing over the first sidewall 21 by the first electrode 42, thereby reducing the impedance of the first electrode 42.

In other similar embodiments, the light-emitting functional layer 41 includes a first light-emitting sub-portion 411, a second light-emitting sub-portion 412, and a third light-emitting sub-portion 413. For structures of the first light-emitting sub-portion 411 and the second light-emitting sub-portion 412, references may be made to those described above. The third light-emitting sub-portion 413 is located on the side of the pixel define layer 2 facing away from the substrate 1. In the same pixel opening 201, the second light-emitting sub-portion 412 is located between the first light-emitting sub-portion 411 and the third light-emitting sub-portion 413 and is connected to the first light-emitting sub-portion 411 and the third light-emitting sub-portion 413.

Specifically, a thickness d3 of the third light-emitting sub-portion 413 is not greater than the thickness d1 of the first light-emitting sub-portion 411.

Due to impact of an evaporation angle, the thickness d3 of the third light-emitting sub-portion 413 may be substantially the same as the thickness d1 of the first light-emitting sub-portion 411, or may be slightly less than the thickness d1 of the first light-emitting sub-portion 411.

The film layer thickness of the first light-emitting sub-portion 411 remains substantially the same at different positions.

In this embodiment, the display panel 10 further includes an isolation structure 3. The isolation structure 3 is located on a side of the pixel define layer 2 facing away from the substrate 1. For the structure of the isolation structure 3, references may be made to the above embodiment, which is not described in detail herein.

The isolation structure 3 encloses a plurality of isolation openings 301. The isolation openings 301 are arranged corresponding to and in communication with the pixel openings 201. An orthographic projection of the pixel opening 201 on the substrate 1 is within the orthographic projection of the isolation opening 301 on the substrate 1.

The first electrode 42 in the light-emitting device 4 covers the side of the light-emitting functional layer 41 facing away from the substrate 1, and is in contact with the sidewall on the side of the isolation structure 3 facing the isolation opening 301.

Specifically, the first electrode 42 overlaps a part of a sidewall on a side of the isolation structure 3 close to the substrate 1.

Referring to FIG. 3 and FIG. 5, the display panel 10 further includes an encapsulation layer.

The encapsulation layer includes a plurality of encapsulation units 5 spaced apart from each other. The encapsulation units 5 are arranged corresponding to the isolation openings 301, and are configured to encapsulate the light-emitting devices 4 arranged in the isolation openings 301.

Specifically, the encapsulation unit 5 includes a first encapsulation portion 51 and a second encapsulation portion 52 that are connected, the first encapsulation portion 51 is located on a side of the first electrode 42 facing away from the substrate 1 and covers a sidewall on the side of the isolation structure 3 facing the isolation opening 301, and the second encapsulation portion 52 is on a side of the isolation structure 3 facing away from the substrate 1.

Referring to FIG. 3 and FIG. 5, the first encapsulation portion 51 covers a side of the light-emitting device 4 facing away from the substrate 1, covers at least part of a sidewall on the side of the isolation structure 3 facing the isolation opening 301, and is connected, through the crown 32 of the isolation structure 3, to the second encapsulation portion 52 located on the side of the isolation structure 3 facing away from the substrate 1.

A gap exists between the second encapsulation portion 52 and the surface on the side of the isolation structure 3 facing away from the substrate 1, in which case the second encapsulation portion 52 is floated relative to the isolation structure 3.

In each isolation opening 301, the encapsulation unit 5 formed by the first encapsulation portion 51 and the second encapsulation portion 52 is a continuous film layer structure, to provide a desirable encapsulation effect for the isolation structure 3 and the light-emitting device 4 located in the isolation opening 301.

In a pixel opening 201, if the slope angle 23 corresponding to the pixel opening 201 is relatively small, the side of the light-emitting device 4 facing away from the substrate 1 can form a relatively flat shape after the light-emitting device 4 is arranged in the isolation opening 301 corresponding to the pixel opening 201. When the encapsulation unit 5 encapsulates the isolation structure 3 and the light-emitting device 4 located in the isolation opening 301, the relatively flat shape helps reduce encapsulation difficulty, thereby avoiding cracks caused by excessively thin encapsulation film layers in a part of an area, and improving a final encapsulation effect.

After the isolation opening 301 is encapsulated using the encapsulation layer, another film layer structure needs to be further arranged on a side of the encapsulation layer facing away from the substrate 1 for further planarization, encapsulation, and the like of the display panel 10.

Specifically, the side of the encapsulation layer facing away from the substrate 1 is further provided with at least one layer of film layer structure among a planarization layer, an organic encapsulation film layer, an inorganic encapsulation film layer, a touch layer, an organic adhesive layer, and a cover plate.

Taking the planarization layer as an example, a material of the planarization layer may include at least one of an organic material or an inorganic material, for example, an organic polymer (such as polyimide or acrylic resin) or an inorganic material (such as silicon oxide or silicon nitride).

The planarization layer made of the organic material may be prepared using a technology such as an ink‑jet printing (IJP) technology. A part of the planarization layer may flow into the isolation opening 301, which fills the isolation opening 301 to improve flatness of the display panel 10, while providing specific protection to the relevant film layers located below the planarization layer. Another part of the planarization layer may cover the above first encapsulation portion 51 and fill a gap formed between the first encapsulation portion 51 and the isolation structure 3. A side surface of the finally prepared planarization layer facing away from the substrate 1 is a flat surface.

It may be understood that, in the display panel 10 provided in this embodiment of the present application, the slope angles 23 in the plurality of pixel openings 201 formed on the pixel define layer 2 may be adjusted, to adjust the display effect of the display panel 10, and improve the accuracy and richness of color display of the display panel 10 to a specific extent.

An embodiment of the present application further provides a preparation method for the above display panel 10.

The preparation method includes the following steps:

Step S1: Prepare a pixel material layer on a side of the substrate 1.

Step S2: Prepare an isolation material layer on a side of the pixel material layer facing away from the substrate 1.

Step S3: Perform etching and patterning on the isolation material layer to form an isolation structure 3, where the isolation structure 3 encloses an isolation opening 301.

Step S4: Perform etching and patterning on the pixel material layer to form a pixel define layer 2, where the pixel define layer 2 encloses a pixel opening 201, and the pixel opening 201 is arranged corresponding to the isolation opening 301.

Step S5: Form a light-emitting device 4 in the isolation opening 301, where the light-emitting device 4 covers the pixel opening 201.

In step S4, etching and patterning are performed on the pixel material layer through dry etching, and the pixel define layer 2 and the pixel opening 201 that have the above structure can be obtained. A first sidewall 21 for forming the pixel opening 201 and a first bottom wall 22 of the pixel define layer 2 can form a slope angle 23 ranging from 30° to 60°. For a structure of an intermediate structure prepared at this time, references may be made to FIG. 6.

In step S5, a light-emitting functional layer 41 and a first electrode 42 in the light-emitting device 4 are sequentially evaporated and attached to the first sidewall 21.

The above method can be used to prepare the pixel define layer 2 having a sloped first sidewall 21.

In a third aspect, the present application further provides a display apparatus 100, including the display panel 10 described in any one of the above embodiments. For a structure thereof, references may be made to FIG. 7.

The display apparatus 100 provided in this embodiment of the present application may be a product or a component with a display function, such as a mobile phone, a notebook computer, a tablet computer, a smart watch, a smart band, a navigator, a display, or a personal digital assistant (PDA).

Since the display panel 10 in the display apparatus 100 has the beneficial effects of any one or more of the above display panels 10, the display apparatus 100 includes at least the beneficial effects of any one or more of the above display panels 10. For the specific effects, references may be to the above descriptions, which are not described herein again.

The above descriptions are merely some embodiments of the present application, and are not intended to limit the present application. Any modification, equivalent replacement, or improvement made without departing from the spirit and principle of the present application shall fall within the protection scope of the present application.

What is claimed is:

1. A display panel, comprising:
a substrate; and
a pixel define layer located on a side of the substrate, wherein the pixel define layer is provided with a plurality of pixel openings, the pixel define layer comprises a first sidewall on a side facing the pixel openings, and the pixel define layer further comprises a first bottom wall on a side facing the substrate, wherein
in a direction perpendicular to a plane in which the substrate is located, an end of the first sidewall close to the substrate intersects the first bottom wall to form a slope angle, and the slope angle is not greater than 60°.

2. The display panel according to claim 1, wherein a material of the pixel define layer comprises an inorganic material.

3. The display panel according to claim 1, wherein the slope angle is not less than 30°.

4. The display panel according to claim 1, wherein a side of the pixel define layer facing away from the substrate is provided with an isolation structure, the isolation structure encloses a plurality of isolation openings, and the isolation openings are arranged corresponding to and in communication with the pixel openings; and
the display panel further comprises a light-emitting device layer, the light-emitting device layer is located on the substrate and comprises a plurality of light-emitting devices located in the corresponding isolation openings, each of the light-emitting devices comprises a light-emitting functional layer and a first electrode, the light-emitting functional layer covers the pixel opening and covers at least part of the first sidewall, and the first electrode covers a side of the light-emitting functional layer facing away from the substrate and is in contact with a sidewall on a side of the isolation structure facing the isolation opening.

5. The display panel according to claim 4, wherein the light-emitting functional layer comprises a first light-emitting sub-portion and a second light-emitting sub-portion, the first light-emitting sub-portion covers the pixel opening, and the second light-emitting sub-portion covers at least part of the first sidewall, and a thickness of the second light-emitting sub-portion is less than a thickness of the first light-emitting sub-portion.

6. The display panel according to claim 5, wherein the plurality of pixel openings comprise at least a first opening and a second opening spaced apart from each other, and the slope angle of the first opening is greater than the slope angle of the second opening; and
a ratio of the thickness of the second light-emitting sub-portion arranged at the first opening to the thickness of the corresponding first light-emitting sub-portion is less than a ratio of the thickness of the second light-emitting sub-portion arranged at the second opening to the thickness of the corresponding first light-emitting sub-portion.

7. The display panel according to claim 6, wherein the second light-emitting sub-portion arranged at the first opening and the second light-emitting sub-portion arranged at the second opening emit light of a same color, and the thickness of the second light-emitting sub-portion arranged at the first opening is less than the thickness of the second light-emitting sub-portion arranged at the second opening.

8. The display panel according to claim 5, wherein a ratio of the thickness of the second light-emitting sub-portion to the thickness of the first light-emitting sub-portion is negatively correlated with a magnitude of the slope angle.

9. The display panel according to claim 5, wherein in the same pixel opening, the thickness of the second light-emitting sub-portion is not less than 50% of the thickness of the first light-emitting sub-portion; and
in the same pixel opening, a ratio of the thickness of the second light-emitting sub-portion to the thickness of the first light-emitting sub-portion ranges from 50% to 95%.

10. The display panel according to claim 5, wherein the light-emitting functional layer further comprises a third light-emitting sub-portion, and the third light-emitting sub-portion is located on a side of the pixel define layer facing away from the substrate;
in the same pixel opening, the second light-emitting sub-portion is located between the first light-emitting sub-portion and the third light-emitting sub-portion and is connected to the first light-emitting sub-portion and the third light-emitting sub-portion; and
in the same pixel opening, a thickness of the third light-emitting sub-portion is not greater than the thickness of the first light-emitting sub-portion.

11. The display panel according to claim 10, wherein an orthographic projection of the third light-emitting sub-portion on the substrate is spaced apart from an orthographic projection of a side of the isolation structure close to the substrate on the substrate.

12. The display panel according to claim 4, wherein the light-emitting device further comprises a second electrode, the second electrode is located between the pixel define layer and the substrate, and an orthographic projection of the pixel opening on the substrate is within an orthographic projection of the second electrode on the substrate; and
the light-emitting functional layer passes through the pixel opening to come into contact with the second electrode.

13. The display panel according to claim 4, wherein the isolation structure comprises a support portion and a crown, and the crown is located on a side of the support portion facing away from the substrate; and
an orthographic projection of the support portion on the substrate is within an orthographic projection of the crown on the substrate.

14. The display panel according to claim 4, further comprising an encapsulation layer, wherein the encapsulation layer comprises a plurality of encapsulation units spaced apart from each other, each of the encapsulation units comprises a first encapsulation portion and a second encapsulation portion that are connected, the first encapsulation portion is located on a side of the first electrode facing away from the substrate and covers the sidewall on the side of the isolation structure facing the isolation opening, and the second encapsulation portion is on a side of the isolation structure facing away from the substrate; and
a gap exists between the second encapsulation portion and a surface on the side of the isolation structure facing away from the substrate.

15. A display panel, comprising:
a substrate; and
a pixel define layer located on a side of the substrate, wherein the pixel define layer is provided with a plurality of pixel openings, the pixel define layer comprises a first sidewall on a side facing the pixel openings, and the pixel define layer further comprises a first bottom wall on a side facing the substrate, wherein
in a direction perpendicular to a plane in which the substrate is located, an end of the first sidewall close to the substrate intersects the first bottom wall to form a slope angle; and the plurality of pixel openings comprise at least a first opening and a second opening spaced apart from each other, and the slope angle of the first opening is greater than the slope angle of the second opening.

16. The display panel according to claim 15, further comprising a light-emitting functional layer arranged corresponding to the pixel openings, wherein the light-emitting functional layer covers the pixel openings and covers at least part of the first sidewall; and
the light-emitting functional layer comprises a first light-emitting sub-portion and a second light-emitting sub-portion, the first light-emitting sub-portion covers the pixel opening, and the second light-emitting sub-portion covers at least part of the first sidewall, and a thickness of the second light-emitting sub-portion is less than a thickness of the first light-emitting sub-portion.

17. The display panel according to claim 16, wherein a ratio of the thickness of the second light-emitting sub-portion arranged at the first opening to the thickness of the corresponding first light-emitting sub-portion is less than a ratio of the thickness of the second light-emitting sub-portion arranged at the second opening to the thickness of the corresponding first light-emitting sub-portion.

18. The display panel according to claim 16, wherein the second light-emitting sub-portion arranged at the first opening and the second light-emitting sub-portion arranged at the second opening emit light of a same color, and the thickness of the second light-emitting sub-portion arranged at the first opening is less than the thickness of the second light-emitting sub-portion arranged at the second opening; and
a ratio of the thickness of the second light-emitting sub-portion to the thickness of the first light-emitting sub-portion is negatively correlated with a magnitude of the slope angle.

19. The display panel according to claim 16, wherein in the same pixel opening, the thickness of the second light-emitting sub-portion is not less than 50% of the thickness of the first light-emitting sub-portion;
in the same pixel opening, a ratio of the thickness of the second light-emitting sub-portion to the thickness of the first light-emitting sub-portion ranges from 50% to 95%; and
the slope angle in the pixel opening is not greater than 60°, and the slope angle is not less than 30°.

20. The display panel according to claim 16, wherein a side of the pixel define layer facing away from the substrate is provided with an isolation structure, the isolation structure encloses a plurality of isolation openings, and the isolation openings are arranged corresponding to and in communication with the pixel openings;
the display panel further comprises a first electrode located in the corresponding isolation opening, and the first electrode covers a side of the light-emitting functional layer facing away from the substrate and is in contact with a sidewall on a side of the isolation structure facing the isolation opening;
the display panel further comprises a second electrode, the second electrode is located between the pixel define layer and the substrate, an orthographic projection of the pixel opening on the substrate is within an orthographic projection of the second electrode on the substrate, and the light-emitting functional layer passes through the pixel opening to come into contact with the second electrode;
the display panel further comprises an encapsulation layer, the encapsulation layer comprises a plurality of encapsulation units spaced apart from each other, each of the encapsulation units comprises a first encapsulation portion and a second encapsulation portion that are connected, the first encapsulation portion is located on a side of the first electrode facing away from the substrate and covers the sidewall on the side of the isolation structure facing the isolation opening, and the second encapsulation portion is on a side of the isolation structure facing away from the substrate; and
a gap exists between the second encapsulation portion and a surface on the side of the isolation structure facing away from the substrate.
